(19) United States
(12) Patent Application Publication
(10) Pub. No.: US 2005/0052914 A1
(43) Pub. Date: Mar. 10, 2005

(54) Semiconductor memory device

(75) Inventors: Hideaki Miyamoto, Ogaki-shi (JP); Naofumi Sakai, Anpachi-gun (JP); Yoshiyuki Ishizuka, Inazawa-shi (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: SANYO ELECTRIC CO., LTD

(21) Appl. No.: 10/932,081

(22) Filed: Sep. 2, 2004

(30) Foreign Application Priority Data
Sep. 8, 2003 (JP) JP2003-314889

(51) Int. Cl. G11C 11/00

(52) U.S. Cl. 365/202

(57) ABSTRACT

A semiconductor memory device allowing miniaturization is provided. This semiconductor memory device comprises a word line and a bit line arranged to intersect with each other, a memory cell array region including a plurality of memory cells connected to the word line and the bit line and a transfer gate transistor arranged under the memory cell array region.

### BACKGROUND OF THE INVENTION

1. Field of the Invention

The present invention relates to a semiconductor memory device, and more particularly, it relates to a semiconductor memory device including memory cells for recording data.

2. Description of the Background Art

A semiconductor memory device including memory cells for recording data is known in general, as disclosed in Japanese Patent Laying-Open No. 6-349267 (1994), for example.

The aforementioned Japanese Patent Laying-Open No. 6-349267 discloses a semiconductor memory device (DRAM: dynamic random access memory) having a hierarchical bit line structure comprising a plurality of word lines arranged to extend in a prescribed direction, a plurality of main bit lines arranged to intersect with the plurality of word lines, sub bit lines connected to the main bit lines through transfer gate transistors and a memory cell array region including a plurality of DRAM cells arranged on the intersectional positions between the word lines and the bit lines. In the DRAM having the hierarchical bit line structure disclosed in Japanese Patent Laying-Open No. 6-349267, gate lines (gate electrodes) of the transfer gate transistors are arranged to extend along the extensional direction of the word lines.

On the other hand, a ferroelectric memory is known as one of nonvolatile memories recently watched with interest. This ferroelectric memory utilizes pseudo capacitance variation with the direction of polarization of a ferroelectric substance as a memory element. This ferroelectric memory, allowing data rewriting at a high speed with a low voltage in principle, is spotlighted as an ideal memory having the advantages of the DRAM, i.e., the high speed and the low voltage, and that of a flash memory, i.e., nonvolatility. Further, a simple matrix (cross-point) ferroelectric memory is known in relation to the ferroelectric memory. Each memory cell of the simple matrix ferroelectric memory is constituted of a ferroelectric capacitor consisting of word line and a bit line formed to extend in intersectional directions respectively and a ferroelectric film arranged between the word line and the bit line. In the simple matrix ferroelectric memory having memory cells each consisted of only the ferroelectric capacitor with no selection transistor, the degree of integration can be improved as compared with a conventional DRAM.

FIG. 9 shows a structure obtained by applying a structure similar to the hierarchical bit line structure of the DRAM disclosed in the aforementioned Japanese Patent Laying-Open No. 6-349267 in relation to the aforementioned simple matrix ferroelectric memory. Referring to FIG. 9, a semiconductor memory device employing this simple matrix ferroelectric memory cells comprise a sub array region (memory cell array region) 101a and transfer gate transistors 104 provided adjacently to the sub array region 101a. A plurality of word lines WL and a plurality of global bit lines GBL as well as a plurality of local bit lines LBL are arranged to intersect with each other.

The sub array region 101a includes a plurality of ferroelectric memory cells 103 provided on the intersectional positions between the plurality of word lines WL and the plurality of local bit lines LBL respectively. The ferroelectric memory cells 103 are constituted of ferroelectric capacitors consisting of the word lines WL, the local bit lines LBL and ferroelectric films (not shown) arranged between the word lines WL and the local bit lines LBL. Each transfer gate transistor 104 is constituted of an n-channel transistor NT101 or NT102. The n-channel transistor NT101 of each transfer gate transistor 104 is constituted of source/drain regions 105a and 105b and a gate line GL102. The n-channel transistor NT102 is constituted of source/drain regions 106a and 106b and a gate line GL103. The source/drain regions 105a, 105b, 106a and 106b and the gate lines GL102 and GL103 of the n-channel transistors NT101 and NT102 are arranged to extend along the extensional direction of the word lines WL.

The local bit lines LBL are connected to the source/drain regions 105a of the n-channel transistors NT101 at nodes 109 shown in FIG. 9, while the global bit lines GBL are connected to the source/drain regions 105b of the n-channel transistors NT101 at nodes 113 in FIG. 9. Thus, the local bit lines LBL are at the same potential as the source/drain regions 105a on regions planarly overlapping with the source/drain regions 105a, while the global bit lines GBL are at the same potential as the source/drain regions 105b on regions planarly overlapping with the source/drain regions 105b. Further, the local bit lines LBL are connected to the source/drain regions 106a of the n-channel transistors NT102 at nodes 111 in FIG. 9 while the global bit lines GBL are connected to the source/drain regions 106b of the n-channel transistors NT102 at nodes 114 in FIG. 9. Thus, the local bit lines LBL are at the same potential as the source/drain regions 106a on regions planarly overlapping with the source/drain regions 106a while the global bit lines GBL are at the same potential as the source/drain regions 106b on regions planarly overlapping with the source/drain regions 106b.

In the conventional simple matrix ferroelectric memory shown in FIG. 9, however, the transfer gate transistors 104 are arranged outside the sub array region 110a, disadvantageously leading to requirement for a plane layout area for both of the sub array region 110a and the transfer gate transistors 104. Thus, the plane layout area is so hard to reduce that it is difficult to miniaturize the semiconductor memory device.

In the conventional simple matrix ferroelectric memory shown in FIG. 9, further, the source/drain regions 105a, 105b, 106a and 106b of the n-channel transistors NT101 and NT102 are arranged to extend perpendicularly to the local bit lines LBL and the global bit lines GBL, leading to small areas of the regions of the source/drain regions 105a, 105b, 106a and 106b of the n-channel transistors NT101 and NT102 overlapping with the local bit lines LBL and the global bit lines GBL at the same potentials (regions not contributing to parasitic capacitances of the local bit lines LBL and the global bit lines GBL). Therefore, it is so difficult to increase the areas of the regions not contributing to the parasitic capacitances of the local bit lines LBL and the global bit lines GBL that the parasitic capacitances of the local bit lines LBL and the global bit lines GBL are hard to reduce.

### SUMMARY OF THE INVENTION

The present invention has been proposed in order to solve the aforementioned problems, and an object of the present invention is to provide a semiconductor memory device allowing miniaturization.

In order to attain the aforementioned object, a semiconductor memory device according to a first aspect of the present invention comprises a word line and a bit line arranged to intersect with each other, a memory cell array region including a plurality of memory cells connected to the word line and the bit line and a transfer gate transistor arranged under the memory cell array region.

In the semiconductor memory device according to the first aspect, the transfer gate transistor is so arranged under the memory cell array region that the plane layout area can be reduced, whereby the semiconductor memory device can be miniaturized.

In the aforementioned semiconductor memory device according to the first aspect, the bit line is preferably arranged to planarly overlap with an impurity region of the transfer gate transistor over at least a partial longitudinal area of the impurity region, and a region of the bit line planarly overlapping with the impurity region of the transfer gate transistor preferably substantially has the same potential as the impurity region of the transfer gate transistor. According to this structure, the bit line and the impurity region of the transfer gate transistor, which are regions not contributing a parasitic capacitance of the bit line, planarly overlap with each other while the areas of the regions having the same potential can be so increased that the parasitic capacitance of the bit line can be easily reduced. In this case, the bit line is preferably arranged to planarly overlap with the impurity region of the transfer gate transistor over the entire longitudinal area of the impurity region.

In the aforementioned semiconductor memory device according to the first aspect, a gate electrode part of the transfer gate transistor is preferably arranged to extend along the extensional direction of the bit line. According to this structure, a plurality of gate electrode parts extending along the extensional direction of the bit line can share a gate line extending along the extensional direction of the word line when the former are connected to the latter. Thus, the number of gate lines can be inhibited from increase, whereby driving current for the semiconductor memory device can be reduced.

In this case, the semiconductor memory device is preferably provided with a plurality of transfer gate transistors, and preferably further comprises a gate line, connected with the gate electrode parts of the plurality of transfer gate transistors, extending along the extensional direction of the word line. According to this structure, the plurality of gate electrode parts can easily share the gate line, whereby the number of gate lines can be easily inhibited from increase.

In the aforementioned semiconductor memory device according to the first aspect, an impurity region of the transfer gate transistor is preferably arranged to extend along the extensional direction of the bit line. According to this structure, the gate electrode part of the transfer gate transistor can be arranged to extend along the extensional direction of the bit line, whereby the number of gate lines can be inhibited from increase when providing a gate line extending along the extensional direction of the word line while connecting a plurality of gate electrode parts to the gate line.

In the aforementioned semiconductor memory device according to the first aspect, the transfer gate transistor preferably includes an n-channel transistor and a p-channel transistor, and at least either the n-channel transistor or the p-channel transistor of the transfer gate transistor is preferably arranged to extend along the extensional direction of the bit line. According to this structure, a plurality of gate electrode parts of at least either the n-channel transistor or the p-channel transistor constituting the transfer gate transistor can be connected to a gate line extending along the extensional direction of the word line, whereby the number of gate lines can be inhibited from increase. Thus, driving current for the semiconductor memory device can be reduced.

In this case, the semiconductor memory device preferably further comprises an additional wiring connecting an impurity region of the n-channel transistor, an impurity region of the p-channel transistor and the bit line with each other. According to this structure, the additional wiring can easily constitute the transfer gate transistor consisting of the n-channel transistor and the p-channel transistor while connecting the impurity regions of the n- and p-channel transistors and the bit line with each other.

In the aforementioned structure including the additional wiring, the additional wiring is preferably connected to the bit line on a position outside the word line located on the outermost position of the memory cell array region. According to this structure, the additional wiring can be connected to the bit line with no inhibition by the word line also when the word line is interposed between the additional wiring and the bit line, whereby the additional wiring can be easily connected to the bit line.

In the aforementioned semiconductor memory device according to the first aspect, the memory cell array region preferably includes a plurality of sub array regions, and the bit line preferably includes a main bit line and a sub bit line connected to the main bit line through the transfer gate transistor and arranged on the plurality of sub array regions. According to this structure, signals can be easily selectively input/output into/from memory cells of a prescribed sub array region by controlling ON and OFF states of the transfer gate transistor, whereby a hierarchical bit line structure can be easily implemented.

In the aforementioned semiconductor memory device according to the first aspect, the memory cells preferably include ferroelectric films arranged between the word line and the bit line on the intersectional position between the word line and the bit line. According to this structure, a simple matrix ferroelectric memory can be miniaturized or a parasitic capacitance of the bit line can be reduced.

A semiconductor memory device according to a second aspect of the present invention comprises a word line and a bit line arranged to intersect with each other, a memory cell array region including a plurality of memory cells connected to the word line and the bit line and a peripheral circuit transistor having an impurity region. The bit line is arranged to planarly overlap with the impurity region of the peripheral circuit transistor at least over a partial longitudinal area of the impurity region, and a region of the bit line planarly overlapping with the impurity region of the peripheral circuit transistor substantially has the same potential as the impurity region of the peripheral circuit transistor.

In the semiconductor memory device according to the second aspect, as hereinabove described, the bit line is arranged to planarly overlap with the impurity region of the peripheral circuit region at least over the partial longitudinal area of the impurity region and the region of the bit line planarly overlapping with the impurity region of the peripheral circuit transistor substantially has the same potential as the impurity region of the peripheral circuit transistor, whereby the bit line and the impurity region of the peripheral circuit transistor, which are regions not contributing to a parasitic capacitance of the bit line, overlap with each other while the areas of the regions having the same potential can be so increased that the parasitic capacitance of the bit line can be reduced. In this case, the bit line is preferably arranged to planarly overlap with the impurity region of the peripheral circuit transistor over the entire longitudinal area of the impurity region.

In the aforementioned semiconductor memory device according to the second aspect, the peripheral circuit transistor is preferably arranged under the memory cell array region. According to this structure, the plane layout area can be so reduced that the semiconductor memory device can be miniaturized.

In the aforementioned semiconductor memory device according to the second aspect, the peripheral circuit transistor may be arranged outside the memory cell array region.

In the aforementioned semiconductor memory device according to the second aspect, a gate electrode part of the peripheral circuit transistor is preferably arranged to extend along the extensional direction of the bit line. According to this structure, a plurality of gate electrode parts extending along the extensional direction of the bit line can share a gate line extending along the extensional direction of the word line when the former are connected to the latter. Thus, the number of gate lines can be inhibited from increase, whereby driving current for the semiconductor memory device can be reduced.

In this case, the semiconductor memory device is preferably provided with a plurality of peripheral circuit transistors, and preferably further comprises a gate line, connected with the gate electrode parts of the plurality of peripheral circuit transistors, extending along the extensional direction of the word line. According to this structure, the plurality of gate electrode parts can easily share the gate line, whereby the number of gate lines can be easily inhibited from increase.

In the aforementioned semiconductor memory device according to the second aspect, the impurity region of the peripheral circuit transistor is preferably arranged to extend along the extensional direction of the bit line. According to this structure, the gate electrode part of the transfer gate transistor can be arranged to extend along the extensional direction of the bit line, whereby the number of gate lines can be inhibited from increase when providing a gate line extending along the extensional direction of the word line while connecting a plurality of gate electrode parts to the gate line.

In the aforementioned semiconductor memory device according to the second aspect, the peripheral circuit transistor preferably includes an n-channel transistor and a p-channel transistor, and at least either the n-channel transistor or the p-channel transistor of the peripheral circuit transistor is preferably arranged to extend along the extensional direction of the bit line. According to this structure, a plurality of gate electrode parts of at least either the n-channel transistor or the p-channel transistor constituting the transfer gate transistor can be connected to a gate line extending along the extensional direction of the word line, whereby the number of the gate lines can be inhibited from increase. Thus, driving current for the semiconductor memory device can be reduced.

In this case, the semiconductor memory device preferably further comprises an additional wiring connecting an impurity region of the n-channel transistor, an impurity region of the p-channel transistor and the bit line with each other. According to this structure, the additional wiring can easily constitute the peripheral circuit transistor consisting of the n-channel transistor and the p-channel transistor while connecting the impurity regions of the n- and p-channel transistors and the bit line with each other.

In the aforementioned structure including the additional wiring, the additional wiring is preferably connected to the bit line on a position outside the word line located on the outermost position of the memory cell array region. According to this structure, the additional wiring can be connected to the bit line with no inhibition by the word line also when the word line is interposed between the additional wiring and the bit line, whereby the additional wiring can be easily connected to the bit line.

In the aforementioned semiconductor memory device according to the second aspect, the memory cell array region preferably includes a plurality of sub array regions, the bit line preferably includes a main bit line and a sub bit line arranged on the plurality of sub array regions, and the peripheral circuit transistor preferably includes a transfer gate transistor interposed between the main bit line and the sub bit line. According to this structure, signals can be easily selectively input/output into/from memory cells of a prescribed sub array region by controlling ON and OFF states of the peripheral transistor, whereby a hierarchical bit line structure can be easily implemented.

In the aforementioned semiconductor memory device according to the second aspect, the memory cells preferably include ferroelectric films arranged between the word line and the bit line on the intersectional position between the word line and the bit line. According to this structure, a simple matrix ferroelectric memory can be miniaturized or a parasitic capacitance of the bit line can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a semiconductor memory device (ferroelectric memory) employing ferroelectric memory cells according to a first embodiment of the present invention;

FIG. 2 is a plane layout diagram of the semiconductor memory device according to the first embodiment shown in FIG. 1;

FIG. 3 is a plane layout diagram of a memory cell array region part of the semiconductor memory device according to the first embodiment shown in FIG. 2;

FIG. 4 is a plane layout diagram of a transfer gate transistor part of the semiconductor memory device according to the first embodiment shown in FIG. 2;

FIG. 5 is a plane layout diagram of a semiconductor memory device employing ferroelectric memory cells according to a second embodiment of the present invention;

FIG. 6 is a plane layout diagram of a semiconductor memory device employing ferroelectric memory cells according to a third embodiment of the present invention;

FIG. 7 is a plane layout diagram of a semiconductor memory device employing ferroelectric memory cells according to a fourth embodiment of the present invention;

FIG. 8 is a plane layout diagram of a semiconductor memory device employing ferroelectric memory cells according to a fifth embodiment of the present invention; and

FIG. 9 is a plane layout diagram showing a structure obtained by applying a structure similar to a hierarchical bit line structure of a conventional DRAM to a simple matrix ferroelectric memory.

### DESCRIPTION OF THE PREFERRED EMBODIMENTS

Embodiments of the present invention are now described with reference to the drawings.

(First Embodiment)

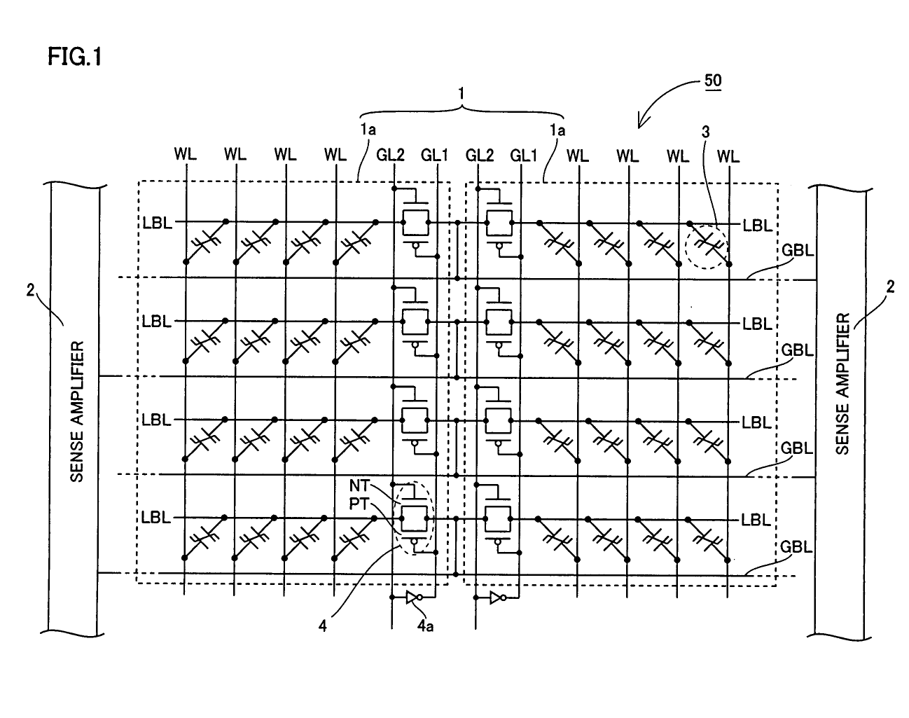

The structure of a semiconductor memory device (ferroelectric memory) 50 according to a first embodiment of the present invention is described with reference to FIGS. 1 to 4.

As shown in FIG. 1, the semiconductor memory device (ferroelectric memory) 50 according to the first embodiment of the present invention comprises a memory cell array region 1 constituted of a plurality of sub array regions 1a. FIG. 1 shows only two sub array regions 1a, in order to simplify the illustration. The semiconductor memory device 50 further comprises a plurality of word lines WL and a plurality of global bit lines GBL as well as a plurality of local bit lines LBL arranged to intersect with each other. The global bit lines GBL are examples of the “main bit line” in the present invention. The local bit lines LBL are examples of the “sub bit line” in the present invention. Sense amplifiers 2 for amplifying signals are connected to the global bit lines GBL. Ferroelectric memories 3 each consisting of a single ferroelectric capacitor are provided on the intersectional positions between the word lines WL and the local bit lines LBL. Each of these ferroelectric memory cells 3 is constituted of the ferroelectric capacitor consisting of each word line WL, each local bit line LBL and a ferroelectric film (not shown) arranged between the word line WL and the local bit line LBL. The ferroelectric memories 3 are examples of the “memory cells” in the present invention.

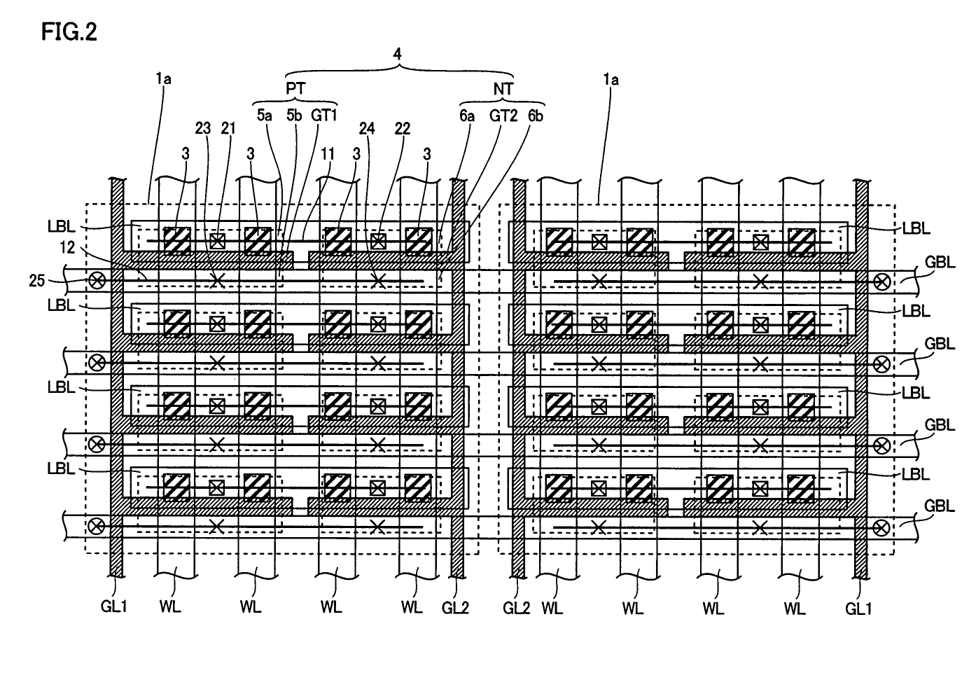

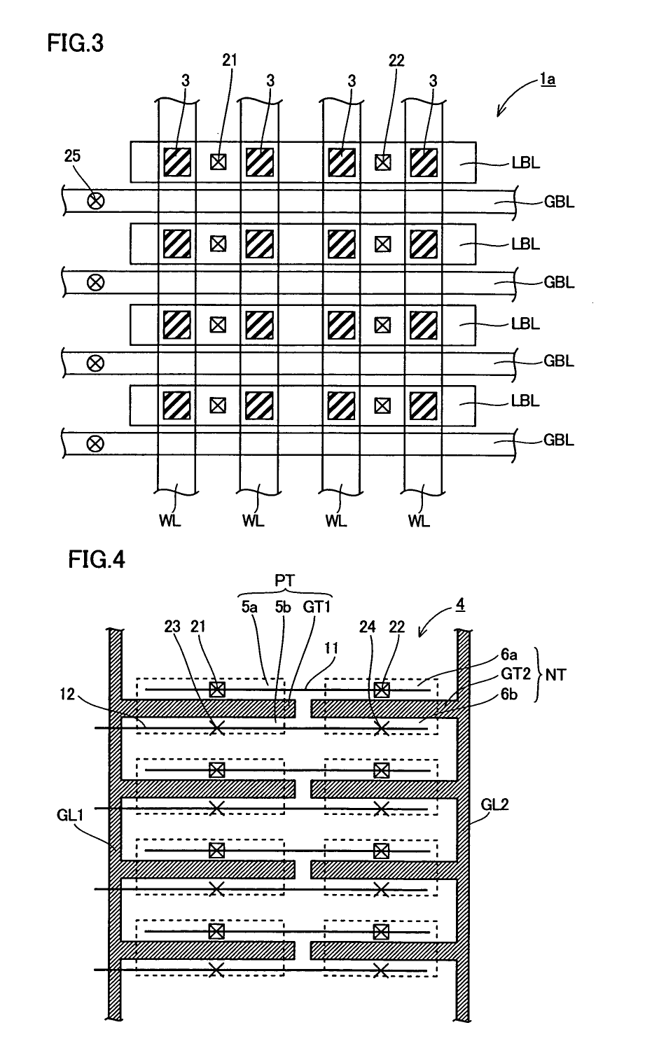

According to the first embodiment, transfer gate transistors 4 are interposed between the global bit lines GBL and the local bit lines LBL, as shown in FIG. 1. The transfer gate transistors 4 are examples of the “peripheral circuit transistor” in the present invention. Each transfer gate transistor 4 is constituted of a CMOS (complementary metal oxide semiconductor) transistor consisting a pair of p- and n-channel transistors PT and NT. An output side of an inverter circuit 4a and a gate line GL1 are connected to the gate of the p-channel transistor PT of the transfer gate transistor 4. Another gate line GL2 is connected to an input side of the inverter circuit 4a and the gate of the n-channel transistor NT of the transfer gate transistor 4. In the sub array regions 1a, the local bit lines LBL are arranged between the plurality of global bit lines GBL, as shown in FIGS. 2 and 3. Each sub array region 1a includes four local bit lines LBL, and has four word lines WL arranged thereon. Further, each sub array region 1a includes 16 ferroelectric memory cells 3.

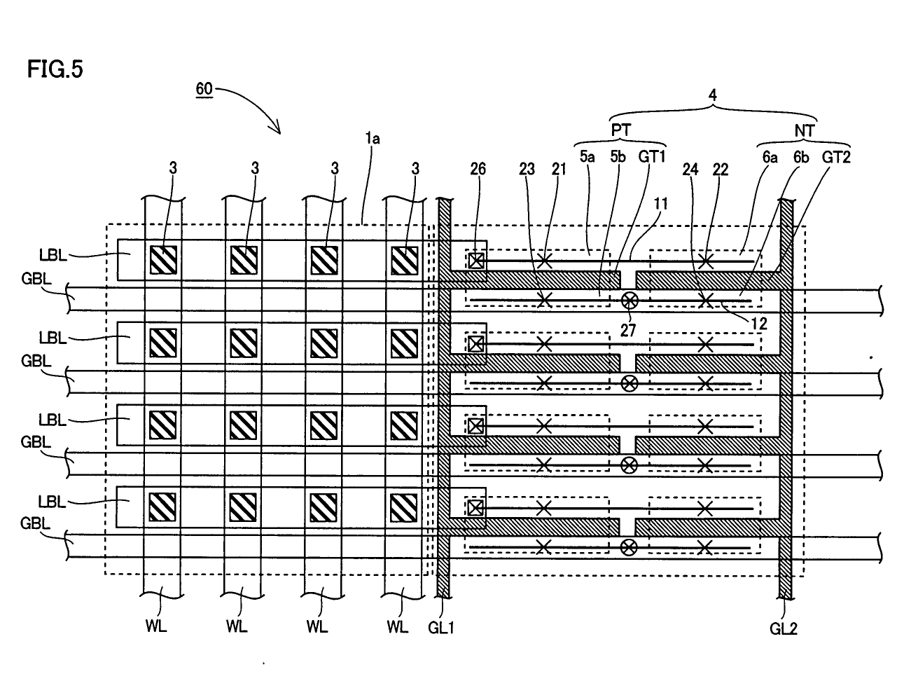

According to the first embodiment, the transfer gate transistors 4 are arranged under the memory cell array region 1, as shown in FIG. 2. Further, the p- and n-channel transistors PT and NT of the transfer gate transistors 4 are arranged to extend along the extensional direction of the global bit lines GBL and the local bit lines LBL. As shown in FIG. 4, the p-channel transistor PT of each transfer gate transistor 4 is constituted of a pair of source/drain regions 5a and 5b and a gate electrode part GT1, while the n-channel transistor NT is constituted of a pair of source/drain regions 6a and 6b and a gate electrode part GT2. The source/drain regions 5a, 5b, 6a and 6b are examples of the “impurity region” in the present invention. As shown in FIG. 2, the source/drain regions 5a, 5b, 6a and 6b and the gate electrode parts GT1 and GT2 of the p- and n-channel transistors PT and NT are arranged to extend along the extensional direction of the global bit lines GBL and the local bit lines LBL. The gate electrode parts GT1 of the plurality of p-channel transistors PT are connected to the single gate line GL1 extending along the extensional direction of the word lines WL in each sub array region 1a. Further, the gate electrode parts GT2 of the plurality of n-channel transistors NT are connected to the other single gate line GL2 extending along the extensional direction of the word lines WL in each sub array region 1a. The gate lines GL1 and GL2 and the gate electrode parts GT1 and GT2 are made of polysilicon or the like.

As shown in FIG. 4, pairs of additional wirings 11 and 12 are arranged above the source/drain regions 5a, 5b, 6a and 6b of the p- and n-channel transistors NT to extend along the extensional direction of the global bit lines GBL and the local bit lines LBL. The additional wirings 11 are connected to the source/drain regions 5a and 6a of the p- and n-channel transistors PT and NT at nodes 21 and 22 respectively. On the other hand, the additional wirings 12 are connected to the source/drain regions 5b and 6b of the p- and n-channel transistors PT and NT at nodes 23 and 24 respectively. As shown in FIGS. 2 and 3, the additional wirings 12 are connected to the global bit lines GBL at nodes 25 positioned outside the word lines WL located on the outermost positions in the sub array regions 1a.

According to the first embodiment, the local bit lines LBL and the source/drain regions 5a of the p-channel transistors PT are arranged to planarly overlap with each other over the entire longitudinal areas of the source/drain regions 5a of the p-channel transistors PT as shown in FIG. 2. Further, the local bit lines LBL are connected to the source/drain regions 5a of the p-channel transistors PT located under the same through contact holes (not shown). Thus, the regions of the local bit lines LBL planarly overlapping with the source/drain regions 5a of the p-channel transistors PT are at the same potential as the source/drain regions 5a of the p-channel transistors PT. Respective regions of the local bit lines LBL and the source/drain regions 5a of the p-channel transistors PT not overlapping with each other are also at the same potential as the regions of the local bit lines LBL and the source/drain regions 5a of the p-channel transistors PT overlapping with each other. The local bit lines LBL are arranged to overlap with the source/drain regions 6a of the n-channel transistors NT over the entire longitudinal areas of the source/drain regions 6a. These local bit lines LBL are connected to the source/drain regions 6a of the n-channel transistors NT located under the same through contact holes (not shown). Thus, the regions of the local bit lines LBL overlapping with the source/drain regions 6a of the n-channel transistors NT are at the same potential as the source/drain regions 6a of the n-channel transistors NT. Respective regions of the local bit lines LBL and the source/drain regions 6a of the n-channel transistors NT not overlapping with each other are also at the same potential as the regions of the local bit lines and the source/drain regions 6a of the n-channel transistors NT overlapping with each other.

A read operation of the semiconductor memory device (ferroelectric memory) 50 according to the first embodiment of the present invention is now described with reference to FIG. 1. In the semiconductor memory device 50 according to the first embodiment, a prescribed row address selection signal is externally input for turning on a certain transfer gate transistor 4 (the p- and n-channel transistors PT and NT) of any sub array region 1a corresponding to the input row address selection signal. On the other hand, the non-selected transfer gate transistors 4 are kept in OFF states. The selected global bit line GBL and the selected local bit line LBL are precharged to 0 V while the selected word line WL rises. Thus, a certain ferroelectric memory cell 3 connected to the rising word line WL outputs a voltage corresponding to data “0” or “1” recorded therein to the local bit line LBL, which in turn transmits this voltage to the global bit line GBL through the ON-state transfer gate transistor 4. The global bit line GBL inputs the transmitted voltage corresponding to the data “0” or “1” of the ferroelectric memory cell 3 in the corresponding sense amplifier 2. Thereafter the sense amplifier 2 is activated at proper timing, thereby amplifying the voltage input therein. Thus, the amplified voltage corresponding to the data “0” or “1” of the ferroelectric memory 3 is output from the sense amplifier 2 for data reading.

According to the first embodiment, as hereinabove described, the transfer gate transistors 4 are so arranged under the memory cell array region 1 that the plane layout area can be reduced, whereby the semiconductor memory device 50 can be miniaturized.

According to the first embodiment, further, the local bit lines LBL are arranged to planarly overlap with the source/drain regions 5a and 6a of the p- and n-channel transistors PT and NT of the transfer gate transistors 4 over the entire longitudinal areas of the source/drain regions 5a and 6a while the regions of the local bit lines LBL planarly overlapping with the source/drain regions 5a and 6a of the transfer gate transistors 4 are at the same potential as the source/drain regions 5a and 6a of the transfer gate transistors 4 so that the local bit lines LBL and the source/drain regions 5a and 6a of the transfer gate transistors 4 not contributing to the parasitic capacitance of the local bit lines LBL planarly overlap with each other and the areas of the regions having the same potential can be reduced, whereby the parasitic capacitance of the local bit lines LBL can be reduced.

According to the first embodiment, in addition, the gate electrode parts GT1 and GT2 of the transfer gate transistors 4 are arranged to extend along the extensional direction of the local bit lines LBL and the global bit lines GBL so that the plurality of gate electrode parts GT1 and GT2 extending along the extensional direction of the local bit lines LBL and the global bit lines GBL can be connected to the gate lines GL1 and GL2 extending along the extensional direction of the word lines WL, whereby the plurality of gate electrode parts GT1 and GT2 can easily share the gate lines GL1 and GL2. Thus, the number of the gate lines GL1 and GL2 can be so inhibited from increase that the driving current for the semiconductor memory device 50 can be reduced.

(Second Embodiment)

Referring to FIG. 5, the structure of a semiconductor memory device (ferroelectric memory) 60 according to a second embodiment of the present invention is described. According to the second embodiment, transfer gate transistors 4 are arranged outside a sub array region 1a, dissimilarly to the aforementioned first embodiment. Further, first ends of local bit lines LBL are arranged to planarly overlap with source/drain regions 5a of p-channel transistors PT of the transfer gate transistors 4 and connected to the source/drain regions 5a through contact holes (not shown) at nodes 26. Thus, regions of the local bit lines LBL planarly overlapping with the source/drain regions 5a of the p-channel transistors PT are at the same potential as the source/drain regions 5a of the p-channel transistors PT. Respective regions of the local bit lines LBL and the source/drain regions 5a of the p-channel transistors PT not overlapping with each other are also at the same potential as the regions of the local bit lines LBL and the source/drain regions 5a of the p-channel transistors PT overlapping with each other. Additional wirings 12 are connected to source/drain regions 5b and 6b of the p-channel transistors PT and n-channel transistors NT at nodes 23 and 24 respectively. Further, the additional wirings 12 are connected to global bit lines GBL at nodes 27 provided on positions corresponding to the spaces between the p- and n-channel transistors PT and NT of the transfer gate transistors 4. The remaining structure and operations of the semiconductor memory device 60 according to the second embodiment are similar to those of the semiconductor memory device 50 according to the aforementioned first embodiment.

In the semiconductor memory device 60 according to the second embodiment, as hereinabove described, gate electrode parts GT1 and GT2 of the p- and n-channel transistors PT and NT of the transfer gate transistors 4 are arranged to extend along the extensional direction of the global bit lines GBL and the local bit lines LBL so that the gate electrode parts GT1 and GT2 extending along the extensional direction of the global bit lines GBL and the local bit lines LBL can be connected to gate lines GL1 and GL2 extending along the extensional direction of word lines WL, whereby the plurality of gate electrode parts GT1 and GT2 can share the gate lines GL1 and GL2. Thus, the number of the gate lines GL1 and GL2 can be inhibited from increase, whereby the driving current for the semiconductor memory device 60 can be reduced similarly to the semiconductor memory device 50 according to the aforementioned first embodiment.

(Third Embodiment)

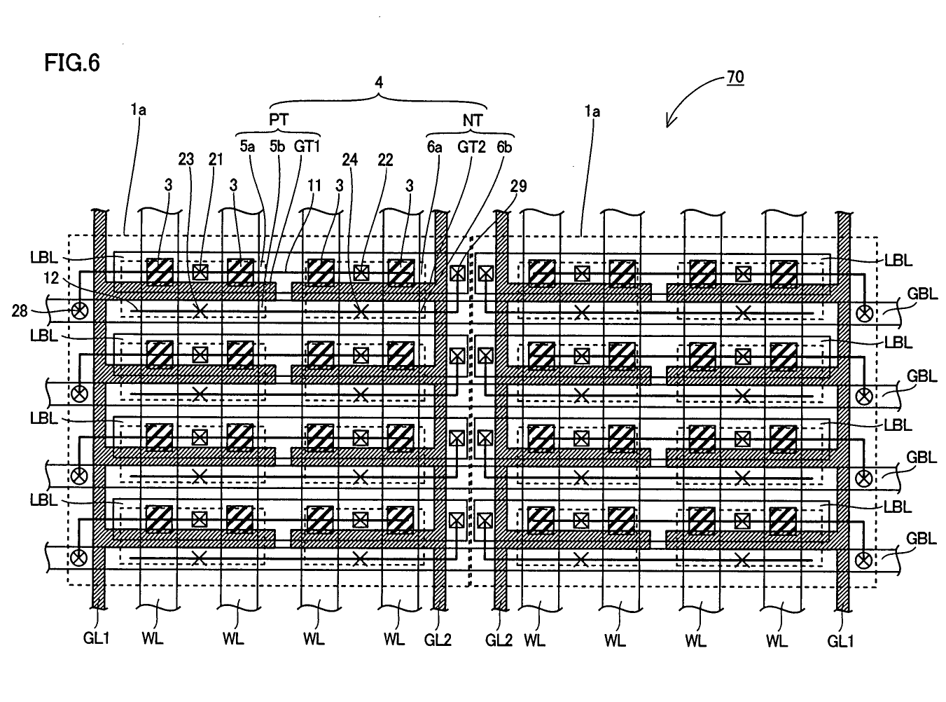

In a semiconductor memory device (ferroelectric memory) 70 according to a third embodiment of the present invention, additional wirings 11 and 12 are connected to global bit lines GBL and local bit lines LBL on positions outside word lines WL located on the outermost positions of sub array regions 1a respectively, as shown in FIG. 6. More specifically, the additional wirings 11 are extended outward beyond the word lines WL adjacent to gate lines GL1 while the extended additional wirings 11 are connected to the global bit lines GBL at nodes 28. On the other hand, the additional wirings 12 are extended outward beyond the word lines WL adjacent to gate lines GL2 while the extended additional wirings 12 are connected to the local bit lines LBL at nodes 29. According to the third embodiment, transfer gate transistors 4 consisting of p- and n-channel transistors PT and NT are arranged under the sub array regions 1a. The remaining structure and operations of the semiconductor memory device 70 according to the third embodiment are similar to those of the semiconductor memory device 50 according to the aforementioned first embodiment.

In the semiconductor memory device 70 according to the third embodiment, the transfer gate transistors 4 are so arranged under the sub array regions 1a that effects such as miniaturization of the semiconductor memory device 70 can be attained similarly to the aforementioned first embodiment.

(Fourth Embodiment)

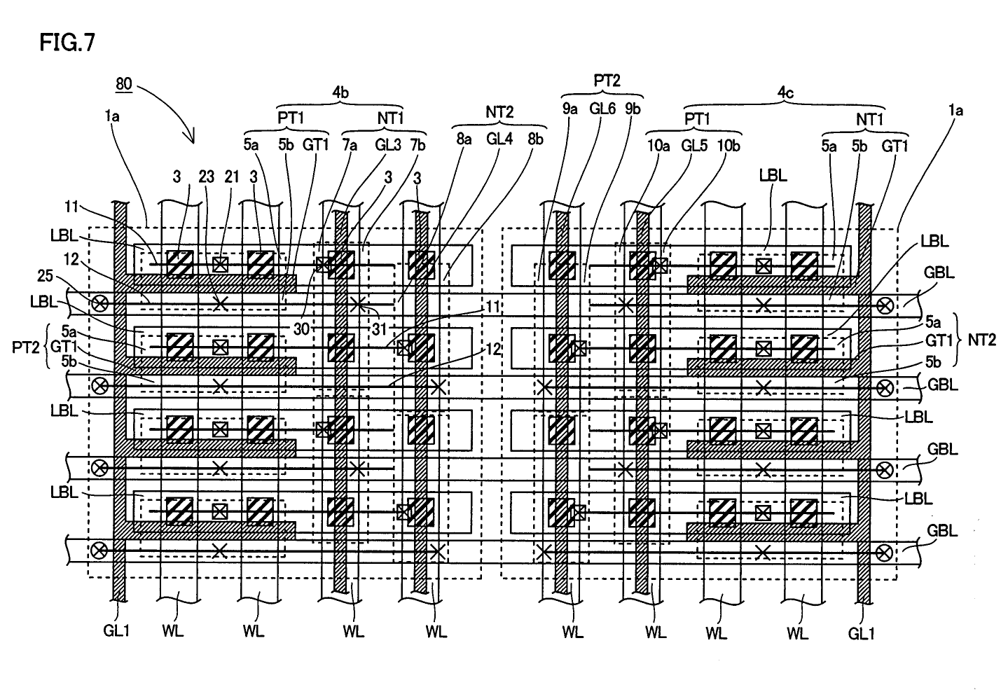

In a semiconductor memory device (ferroelectric memory) 80 according to a fourth embodiment of the present invention, only either p-channel transistors or n-channel transistors constituting transfer gate transistors 4b and 4c are arranged to extend along global bit lines GBL and local bit lines LBL, as shown in FIG. 7.

More specifically, certain transfer gate transistors 4b are constituted of CMOS transistors consisting of p-channel transistors PT1 and n-channel transistors NT1 respectively while other transfer gate transistors 4b are constituted of CMOS transistors consisting of p-channel transistors PT2 and n-channel transistors NT2 respectively. The p-channel transistors PT1 and PT2 constituting the transfer gate transistors 4b are arranged to extend along the extensional direction of the global bit lines GBL and the local bit lines LBL, while the n-channel transistors NT1 and NT2 are arranged to extend along the extensional direction of word lines WL. The n-channel transistors NT1 are constituted of source/drain regions 7a and 7b and a gate line GL3, while the n-channel transistors NT2 are constituted of source/drain regions 8a and 8b and a gate line GL4.

The pair of gate lines GL3 and GL4 are arranged under the word lines WL to extend along the extensional direction of the word lines WL. The source/drain regions 7a, 7b, 8a and 8b of the n-channel transistors NT1 and NT2 are arranged to extend along the extensional direction of the word lines WL and the gate liens GL3 and GL4. While FIG. 7 illustrates only single n-channel transistors NT1 and NT2, a plurality of n-channel transistors NT1 and a plurality of n-channel transistors NT2 are arranged along the pair of gate lines GL3 and GL4 according to the fourth embodiment.

Additional wirings 11 are connected to source/drain regions 5a and 7a of the p- and n-channel transistors PT1 and NT1 at nodes 21 and 30 respectively. Additional wirings 12 are connected to source/drain regions 5b and 7b of the p- and n-channel transistors PT1 and NT1 at nodes 23 and 31 respectively. Further, the additional wirings 12 are connected to the global bit lines GBL at nodes 25 positioned outside the word lines WL adjacent to gate lines GL1. The local bit lines LBL are connected to the source/drain regions 7a of the n-channel transistors NT1 located under the same through contact holes (not shown). Thus, regions of the local bit lines LBL planarly overlapping with the source/drain regions 7a of the n-channel transistors NT1 are at the same potential as the source/drain regions 7a of the n-channel transistors NT1. Respective regions of the local bit lines LBL and the source/drain regions 7a of the n-channel transistors NT1 not overlapping with each other are also at the same potential as the regions of the local bit lines LBL and the source/drain regions 7a of the n-channel transistors NT1 overlapping with each other.

As to the transfer gate transistors 4b consisting of the p- and n-channel transistors PT2 and NT2, the additional wirings 11 connect the source/drain regions 5a and 8a of the p- and n-channel transistors PT2 and NT2 with each other while the additional wirings 12 connect the source/drain regions 5b and 8b of the p- and n-channel transistors PT2 and NT2 with each other. The local bit lines LBL are connected to the source/drain regions 8a of the n-channel transistors NT2 located under the same through contact holes (not shown). Thus, regions of the local bit lines LBL planarly overlapping with the source/drain regions 8a of the n-channel transistors NT2 are at the same potential as the source/drain regions 8a of the n-channel transistors NT2. Respective regions of the local bit lines LBL and the source/drain regions 8a of the n-channel transistors NT2 not overlapping with each other are also at the same potential as the regions of the local bit lines LBL and the source/drain regions 8a of the n-channel transistors NT2 overlapping with each other. The remaining structures of the transfer gate transistors 4b consisting of the p- and n-channel transistors PT2 and NT2 are similar to those of the aforementioned transfer gate transistors 4b consisting of the p- and n-channel transistors PT1 and NT1.

The plurality of transfer gate transistors 4c are arranged adjacently to the transfer gate transistors 4b. The plurality of transfer gate transistors 4c are constituted of CMOS transistors consisting of p- and n-channel transistors PT1 and NT1 and CMOS transistors consisting of p- and n-channel transistors PT2 and NT2 respectively. The n-channel transistors NT1 and NT2 constituting the transfer gate transistors 4c are arranged to extend along the extensional direction of the local bit lines LBL and the global bit lines GBL while the p-channel transistors PT1 and PT2 are arranged to extend along the extensional direction of the word lines WL. The p-channel transistors PT1 are constituted of source/drain regions 10a and 10b and a gate line GL5. The p-channel transistors PT2 are constituted of source/drain regions 9a and 9b and a gate line GL6. The pair of gate lines GL5 and GL6 are arranged under the word lines WL to extend along the extensional direction of the word lines WL. The source/drain regions 10a, 10b, 9a and 9b of the p-channel transistors PT1 and PT2 are arranged to extend along the extensional direction of the word lines WL and the gate lines GL5 and GL6. The remaining structure and operations of the semiconductor memory device 80 according to the fourth embodiment are similar to those of the semiconductor memory device 50 according to the aforementioned first embodiment.

In the semiconductor memory device 80 according to the fourth embodiment, as hereinabove described, the p- and n-channel transistors PT1, PT2, NT1 and NT2 of the transfer gate transistors 4b and 4c are arranged to extend along the extensional direction of the global bit lines GBL and the local bit lines LBL so that gate electrode parts GT1 of the p- and n-channel transistors PT1, PT2, NT1 and NT2 extending along the extensional direction of the global bit lines GBL and the local bit lines LBL can be connected to the gate lines GL1, extending along the extensional direction of the word lines WL, provided in correspondence thereto respectively, whereby the plurality of gate electrode parts GT1 can share the gate lines GL1. Thus, the number of the gate lines GL1 and GL3 to GL6 can be inhibited from increase, whereby the driving current for the semiconductor memory device 80 can be reduced.

The remaining effects of the semiconductor memory device 80 according to the fourth embodiment are similar to those of the semiconductor memory device 50 according to the aforementioned first embodiment.

(Fifth Embodiment)

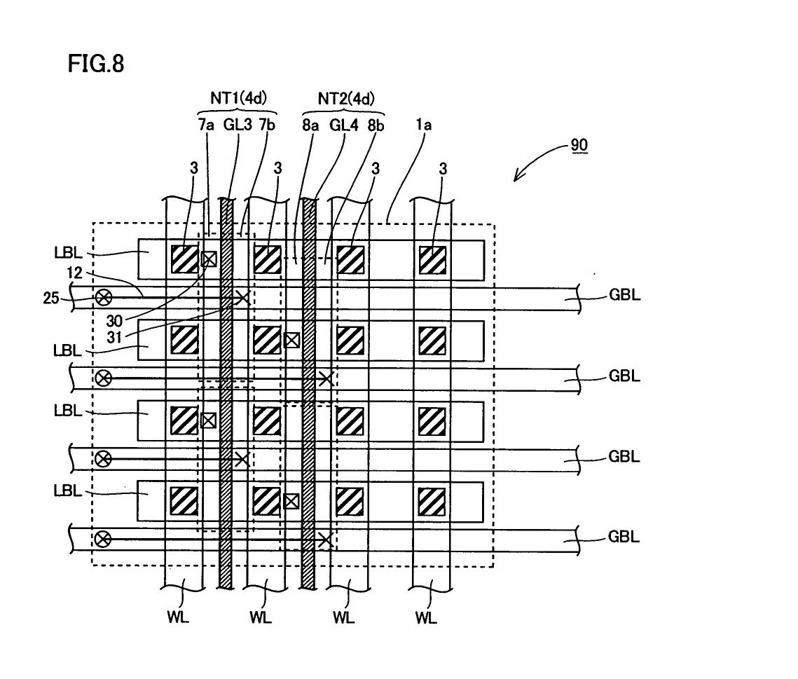

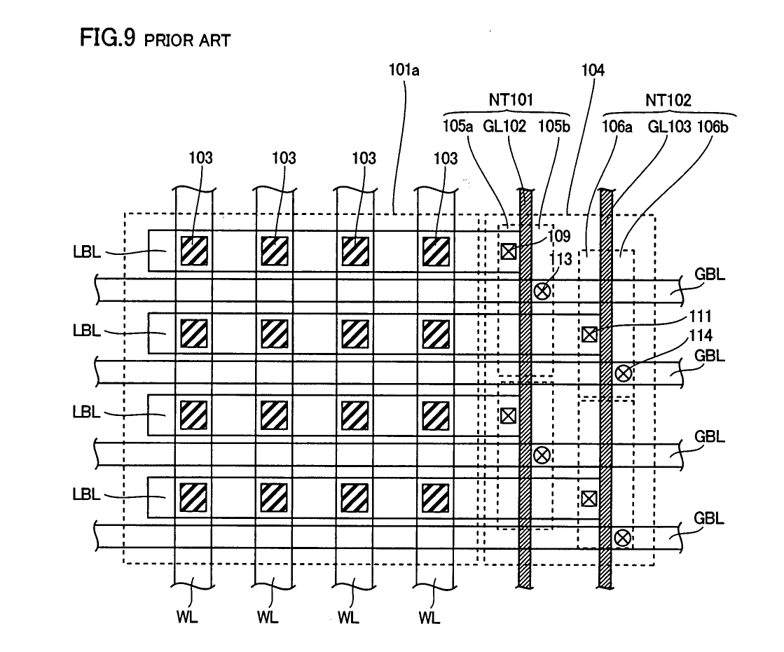

In a semiconductor memory device (ferroelectric memory) 90 according to a fifth embodiment of the present invention, the structure of each transfer gate transistor 4d corresponds to that obtained by removing the p-channel transistors PT1 and PT2 from each transfer gate transistor 4b of the semiconductor memory device 80 according to the aforementioned fourth embodiment, as shown in FIG. 8. In other words, each transfer gate transistor 4d of the semiconductor memory device 90 according to the fifth embodiment is constituted of only either n-channel transistor NT1 or NT2. According to the fifth embodiment, the transfer gate transistors 4d are arranged under a sub array region 1a while the n-channel transistors NT1 and NT2 constituting the transfer gate transistors 4d are arranged to extend along the extensional direction of word lines WL. Each of gate lines GL2 and GL3 is arranged between an adjacent pair of word lines. The remaining structure and operations of the semiconductor memory device 90 according to the fifth embodiment are similar to those of the semiconductor memory device 50 according to the aforementioned first embodiment.

In the semiconductor memory device 90 according to the fifth embodiment, the transfer gate transistors 4d consisting of the n-channel transistors NT1 and NT2 are arranged under the sub array region 1a, whereby the semiconductor memory device 90 can be miniaturized.

Although the present invention has been described and illustrated in detail, it is clearly understood that the same is by way of illustration and example only and is not to be taken by way of limitation, the spirit and scope of the present invention being limited only by the terms of the appended claims.

For example, while the transfer gate transistors are constituted of the CMOS transistors consisting of the p- and n-channel transistors or only the n-channel transistors in each of the aforementioned first to fifth embodiments, the present invention is not restricted to this but the transfer gate transistors may alternatively be constituted of only p-channel transistors.

While the gate electrode parts and the gate lines are made of a material such as polysilicon in each of the aforementioned embodiments, the present invention is not restricted to this but only the gate lines may alternatively be made of another material having lower resistance than polysilicon. Thus, the resistance values of the gate lines can be so reduced that signal transmission can be inhibited from delay in the gate lines also when the gate lines are increased in length.

While the transfer gate transistors 4 are arranged under the sub array regions 1a in the aforementioned third embodiment, the present invention is not restricted to this but the transfer gate transistors 4 may alternatively be arranged outside the sub array regions 1a. Also in this case, the p- and n-channel transistor PT and NT constituting the transfer gate transistors 4 are arranged to extend along the extensional direction of the global bit lines GBL and the local bit lines LBL so that the gate electrode parts GT1 and GT2 of the transfer gate transistors 4 are arranged to extend along the extensional direction of the global bit lines GBL and the local bit lines LBL, whereby the gate electrode parts GT1 and GT2 of the transfer gate transistors 4 can be connected to the gate lines GL1 and GL2 extending along the extensional direction of the word lines WL. Thus, the plurality of gate electrode parts GT1 and GT2 can share the gate lines GL1 and GL2, whereby the number of the gate lines GL1 and GL2 can be inhibited from increase. Therefore, the driving current for the semiconductor memory device 70 can be reduced. Also in this case, signal transmission can be inhibited from delay in the gate lines GL1 and GL2 when only the gate lines GL1 and GL2 are made of another material having lower resistance than polysilicon.

While the additional wirings connected to the source/drain regions of the transfer gate transistors are connected to the global bit lines GBL on the positions outside the word lines WL located on the outermost positions of the sub array regions thereby connecting the global bit lines GBL and the source/drain regions of the transfer gate transistors with each other in each of the aforementioned first and third to fifth embodiments, the present invention is not restricted to this but the global bit lines GBL and the source/drain regions of the transfer gate transistors may alternatively be directly connected with each other without through the additional wirings. Particularly when the word lines WL and the local bit lines LBL are arranged at loose pitches, the global bit lines GBL and the source/drain regions of the transfer gate transistors located under the same can be easily connected with each other through contact holes.

While the present invention is applied to the semiconductor memory device having the hierarchical bit line structure connecting the global bit lines GBL and the local bit lines LBL with each other through the transfer gate transistors in each of the aforementioned embodiments, the present invention is not restricted to this but may alternatively be applied to a semiconductor memory device having a hierarchical word line structure connecting global bit lines and local word lines with each other through transfer gate transistors. Also in this case, effects similar to those of the semiconductor memory device having the hierarchical bit line structure according to each of the aforementioned embodiments can be attained.

1. A semiconductor memory device comprising:
a word line and a bit line arranged to intersect with each other;
a memory cell array region including a plurality of memory cells connected to said word line and said bit line; and
a transfer gate transistor arranged under said memory cell array region.

2. The semiconductor memory device according to claim 1, wherein
said bit line is arranged to planarly overlap with an impurity region of said transfer gate transistor over at least a partial longitudinal area of said impurity region, and
a region of said bit line planarly overlapping with said impurity region of said transfer gate transistor substantially has the same potential as said impurity region of said transfer gate transistor.

3. The semiconductor memory device according to claim 2, wherein
said bit line is arranged to planarly overlap with said impurity region of said transfer gate transistor over the entire longitudinal area of said impurity region.

4. The semiconductor memory device according to claim 1, wherein
a gate electrode part of said transfer gate transistor is arranged to extend along the extensional direction of said bit line.

5. The semiconductor memory device according to claim 4, provided with a plurality of said transfer gate transistors, further comprising a gate line, connected with said gate electrode parts of said plurality of transfer gate transistors, extending along the extensional direction of said word line.

6. The semiconductor memory device according to claim 1, wherein
an impurity region of said transfer gate transistor is arranged to extend along the extensional direction of said bit line.

7. The semiconductor memory device according to claim 1, wherein
said transfer gate transistor includes an n-channel transistor and a p-channel transistor, and
at least either said n-channel transistor or said p-channel transistor of said transfer gate transistor is arranged to extend along the extensional direction of said bit line.

8. The semiconductor memory device according to claim 7, further comprising an additional wiring connecting an impurity region of said n-channel transistor, an impurity region of said p-channel transistor and said bit line with each other.

9. The semiconductor memory device according to claim 8, wherein
said additional wiring is connected to said bit line on a position outside said word line located on the outermost position of said memory cell array region.

10. The semiconductor memory device according to claim 1, wherein
said memory cell array region includes a plurality of sub array regions, and
said bit line includes a main bit line and a sub bit line connected to said main bit line through said transfer gate transistor and arranged on said plurality of sub array regions.

11. The semiconductor memory device according to claim 1, wherein
said memory cells include ferroelectric films arranged between said word line and said bit line on the intersectional position between said word line and said bit line.

12. A semiconductor memory device comprising:
a word line and a bit line arranged to intersect with each other;
a memory cell array region including a plurality of memory cells connected to said word line and said bit line; and
a peripheral circuit transistor having an impurity region, wherein
said bit line is arranged to planarly overlap with said impurity region of said peripheral circuit transistor at least over a partial longitudinal area of said impurity region, and
a region of said bit line planarly overlapping with said impurity region of said peripheral circuit transistor substantially has the same potential as said impurity region of said peripheral circuit transistor.

13. The semiconductor memory device according to claim 12, wherein
said bit line is arranged to planarly overlap with said impurity region of said peripheral circuit transistor over the entire longitudinal area of said impurity region.

14. The semiconductor memory device according to claim 12, wherein
said peripheral circuit transistor is arranged under said memory cell array region.

15. The semiconductor memory device according to claim 12, wherein
said peripheral circuit transistor is arranged outside said memory cell array region.

16. The semiconductor memory device according to claim 12, wherein
a gate electrode part of said peripheral circuit transistor is arranged to extend along the extensional direction of said bit line.

17. The semiconductor memory device according to claim 16, provided with a plurality of said peripheral circuit transistors, further comprising a gate line, connected with said gate electrode parts of said plurality of peripheral circuit transistors, extending along the extensional direction of said word line.

18. The semiconductor memory device according to claim 12, wherein
said impurity region of said peripheral circuit transistor is arranged to extend along the extensional direction of said bit line.

19. The semiconductor memory device according to claim 12, wherein
said peripheral circuit transistor includes an n-channel transistor and a p-channel transistor, and
at least either said n-channel transistor or said p-channel transistor of said peripheral circuit transistor is arranged to extend along the extensional direction of said bit line.

20. The semiconductor memory device according to claim 19, further comprising an additional wiring connecting an impurity region of said n-channel transistor, an impurity region of said p-channel transistor and said bit line with each other.

21. The semiconductor memory device according to claim 20, wherein
said additional wiring is connected to said bit line on a position outside said word line located on the outermost position of said memory cell array region.

22. The semiconductor memory device according to claim 12, wherein
said memory cell array region includes a plurality of sub array regions,
said bit line includes a main bit line and a sub bit line arranged on said plurality of sub array regions, and
said peripheral circuit transistor includes a transfer gate transistor interposed between said main bit line and said sub bit line.

23. The semiconductor memory device according to claim 12, wherein
said memory cells include ferroelectric films arranged between said word line and said bit line on the intersectional position between said word line and said bit line.
